(19) United States
(12) Patent Application Publication
(10) Pub. No.: US 2026/0110941 A1
(43) Pub. Date: Apr. 23, 2026

(54) Display Panel and Electronic Device

(71) Applicant: VIVO MOBILE COMMUNICATION CO., LTD., Dongguan (CN)

(72) Inventors: Zipeng Su, Dongguan (CN); Shigao Zhang, Dongguan (CN)

(21) Appl. No.: 19/424,533

(22) Filed: Dec. 18, 2025

Related U.S. Application Data
(63) Continuation of application No. PCT/CN2024/101716, filed on Jun. 26, 2024.

(30) Foreign Application Priority Data
Jun. 27, 2023 (CN) 202310765745.6

(51) Int. Cl. G02F 1/167; G02F 1/1675; G02F 1/1677; G02F 1/1685; H10H 20/841

(52) U.S. Cl. CPC G02F 1/167; G02F 1/1677; G02F 1/1685; H10H 20/841; G02F 2001/1678

(57) ABSTRACT

A display panel includes a display panel body, where the display panel body includes a first display surface and a second display surface that are disposed in a back-to-back manner; a light-emitting diode disposed on the display panel body; and an electrophoretic structure disposed on the display panel body. The electrophoretic structure includes a first electrode layer, an electrophoretic cavity, and a second electrode layer that are sequentially disposed in a stacked manner, the electrophoretic cavity is disposed corresponding to the light-emitting diode, and the electrophoretic cavity is filled with an electrophoretic liquid and electrophoretic particles. During display on the first display surface, the electrophoretic particles aggregate on the second electrode layer and form a first reflective layer; and during display on the second display surface, the electrophoretic particles aggregate on the first electrode layer and form a second reflective layer.

### CROSS-REFERENCE TO RELATED APPLICATIONS

This application is a Bypass Continuation Application of International Patent Application No. PCT/CN2024/101716 filed Jun. 26, 2024, and claims priority to Chinese Patent Application No. 202310765745.6 filed Jun. 27, 2023, the disclosures of which are hereby incorporated by reference in their entireties.

### BACKGROUND OF THE INVENTION

### Field of the Invention

This application relates to the technical field of electronic products, and in particular, to a display panel and an electronic device.

### Description of Related Art

With the advancement of technologies, more electronic products use a double-sided display design solution. Especially in electronic products such as a foldable mobile phone, to enable display functionality even after being folded, a double-sided display design solution is usually employed on at least one folding part.

### SUMMARY OF THE INVENTION

According to a first aspect, embodiments of this application provide a display panel, including:
a display panel body, where the display panel body includes a first display surface and a second display surface that are disposed in a back-to-back manner;
a light-emitting diode, where the light-emitting diode is disposed on the display panel body; and
an electrophoretic structure, where the electrophoretic structure is disposed on the display panel body, the electrophoretic structure is located between the first display surface and the second display surface, the electrophoretic structure includes a first electrode layer, an electrophoretic cavity, and a second electrode layer that are sequentially disposed in a stacked manner, the electrophoretic cavity is disposed corresponding to the light-emitting diode, the first electrode layer is disposed on a side on which the first display surface is located, the second electrode layer is disposed on a side on which the second display surface is located, and the electrophoretic cavity is filled with an electrophoretic liquid and electrophoretic particles.

During display on the first display surface, the electrophoretic particles aggregate on the second electrode layer and form a first reflective layer; and during display on the second display surface, the electrophoretic particles aggregate on the first electrode layer and form a second reflective layer.

According to a second aspect, embodiments of this application provide an electronic device, including the display panel according to the first aspect.

### BRIEF DESCRIPTION OF THE DRAWINGS

The foregoing and/or additional aspects and advantages of this application will become apparent and comprehensible in the description of the embodiments made with reference to the following accompanying drawings.

FIG. 1 is a first diagram of a structure of a display panel according to an embodiment of this application;

FIG. 2 is a partially enlarged view of a region A in FIG. 1;

FIG. 3 is a second diagram of a structure of a display panel according to an embodiment of this application;

FIG. 4 is a partially enlarged view of a region B in FIG. 3;

FIG. 5 is a first diagram of a structure of an electrophoretic particle shown in FIG. 2;

FIG. 6 is a second diagram of a structure of an electrophoretic particle shown in FIG. 2;

FIG. 7 is a diagram of a structure of a light-emitting diode shown in FIG. 1;

FIG. 8 is a partial top view of the display panel shown in FIG. 1;

FIG. 9 is a top view of a touch structure of the display panel shown in FIG. 1;

FIG. 10 is a partial top view of a region C in FIG. 9;

FIG. 11 is a third diagram of a structure of a display panel according to an embodiment of this application;

FIG. 12 is a diagram of integration of an electrophoretic structure and a light-emitting diode in FIG. 11; and

FIG. 13 is a diagram of a structure of a foldable mobile phone according to an embodiment of this application.

### DESCRIPTION OF THE INVENTION

Currently, two independent screens are usually disposed in a back-to-back manner, to implement the double-sided display design solution. However, disposing two independent screens in the back-to-back manner may cause an increase in an overall thickness of the electronic product, and then increase thickness costs of the electronic product.

In view of the above, the current double-sided display design solution has a problem of high thickness costs.

Embodiments of this application are described in detail below, and examples of the embodiments are shown in accompanying drawings, where the same or similar elements or the elements having same or similar functions are denoted by the same or similar reference numerals throughout the accompanying drawings. The embodiments described below with reference to the accompanying drawings are examples and used only for explaining this application, and should not be construed as a limitation on this application. All other embodiments obtained by a person of ordinary skill in the art based on the embodiments of this application shall fall within the protection scope of this application.

In the specification and the claims of this application, a feature limited by the term “first” or “second” may explicitly or implicitly include one or more of the features. In the description of this application, unless otherwise stated, “a plurality of” means two or more than two. In addition, in the specification and the claims, “and/or” indicates at least one of connected objects, and the character “/”generally indicates an “or”relationship between associated objects.

In the description of this application, it should be noted that unless otherwise explicitly specified or defined, the terms “mount”, “connect”, and “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two elements. A person of ordinary skill in the art may understand the meanings of the foregoing terms in this application according to actual situations.

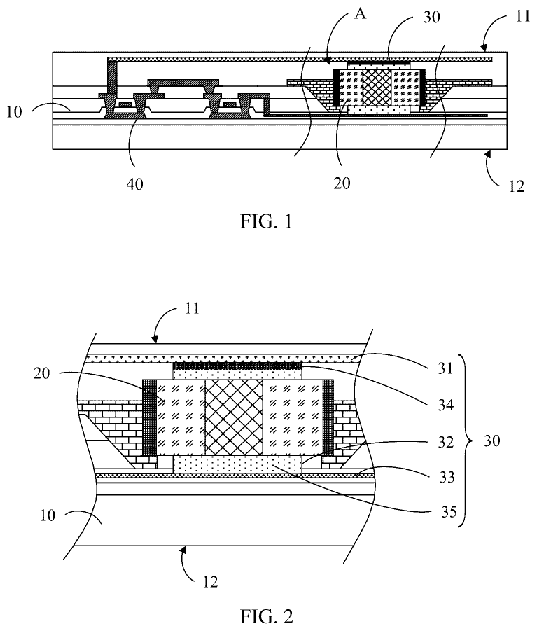

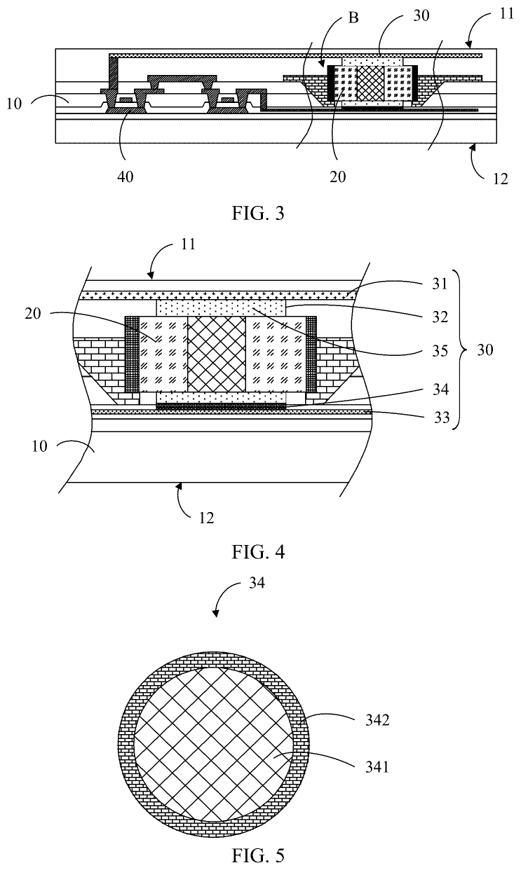

Referring to FIG. 1 to FIG. 4, FIG. 1 is a first diagram of a structure of a display panel according to an embodiment of this application; FIG. 2 is a partially enlarged view of a region A in FIG. 1; FIG. 3 is a second diagram of a structure of a display panel according to an embodiment of this application; and FIG. 4 is a partially enlarged view of a region B in FIG. 3. As shown in FIG. 1 to FIG. 4, embodiments of this application provide a display panel. The display panel includes:
a display panel body 10, where the display panel body 10 includes a first display surface 11 and a second display surface 12 that are disposed in a back-to-back manner;
a light-emitting diode 20, where the light-emitting diode 20 is disposed on the display panel body 10; and
an electrophoretic structure 30, where the electrophoretic structure 30 is disposed on the display panel body 10, the electrophoretic structure 30 is located between the first display surface 11 and the second display surface 12, the electrophoretic structure 30 includes a first electrode layer 31, an electrophoretic cavity 32, and a second electrode layer 33 that are sequentially disposed in a stacked manner, the electrophoretic cavity 32 is disposed corresponding to the light-emitting diode 20, the first electrode layer 31 is disposed on a side on which the first display surface 11 is located, the second electrode layer 33 is disposed on a side on which the second display surface 12 is located, and the electrophoretic cavity 32 is filled with an electrophoretic liquid 35 and electrophoretic particles 34.

During display on the first display surface 11, the electrophoretic particles 34 aggregate on the second electrode layer 33 and form a first reflective layer, which is shown in FIG. 2. During display on the second display surface 12, the electrophoretic particles 34 aggregate on the first electrode layer 31 and form a second reflective layer, which is shown in FIG. 4.

The foregoing display panel body 10 may be understood as a main structure of the display panel, and includes, but is not limited to, structures such as a display substrate, a reflector, and a cover plate. The light-emitting diode 20 may be integrally disposed in the display panel body 10. In addition, a driver circuit 40 of the display panel may further be integrally disposed in the display panel body 10. The light-emitting diode 20 may be electrically connected to the driver circuit 40, to implement a display function of the display panel. The driver circuit 40 may include a driver circuit thin film transistor.

The foregoing light-emitting diode 20 may be a micro light emitting diode display (Micro Light Emitting Diode Display, micro LED). A length of the light-emitting diode 20 may be 0.1 um to 100 um, for example, 25 um. Correspondingly, a width of the light-emitting diode 20 may be 0.1 um to 100 um, for example, 10 um.

The foregoing display panel body 10 may be provided with an accommodating cavity adapted to the electrophoretic structure 30, so that the electrophoretic structure 30 can be assembled inside the display panel body 10, and the electrophoretic structure 30 is located between the first display surface 11 and the second display surface 12. In addition, the electrophoretic cavity 32 may be disposed corresponding to the light-emitting diode 20 in the accommodating cavity. That the electrophoretic cavity 32 is disposed corresponding to the light-emitting diode 20 may be understood as that the light-emitting diode 20 is disposed in the electrophoretic cavity 32 in a penetrating manner. For example, it may be understood that a light-emitting layer of the light-emitting diode 20 is located inside the electrophoretic cavity 32, so that light emitted by the light-emitting diode 20 may exit through the electrophoretic cavity 32.

The foregoing electrophoretic cavity 32 may include two openings. That the foregoing first electrode layer 31, the foregoing electrophoretic cavity 32, and the foregoing second electrode layer 33 are sequentially disposed in the stacked manner may be understood as that the first electrode layer 31 and the second electrode layer 33 are respectively disposed corresponding to the two openings of the electrophoretic cavity 32, to separately block the two openings and form the electrophoretic cavity 32 into a sealed space. The sealed space may be filled with the electrophoretic liquid 35 and the electrophoretic particles 34. When one of the first electrode layer 31 and the second electrode layer 33 is energized, the electrophoretic particles 34 may migrate through the electrophoretic liquid and aggregate on a side on which the energized electrode layer is located, and form a corresponding reflective layer. The reflective layer can reflect light emitted by the light-emitting diode 20. After being reflected, the light emitted by the light-emitting diode 20 can exit through a side on which the non-energized electrode layer is located.

As shown in FIG. 1 to FIG. 4, the foregoing driver circuit 40 may further be electrically connected to the first electrode layer 31 and the second electrode layer 33, so as to supply power to the first electrode layer 31 or the second electrode layer 33, and cause the electrophoretic particles 34 to migrate through the electrophoretic liquid, aggregate on the side on which the energized electrode layer is located, and form the corresponding reflective layer.

It may be understood that, in this application, the electrophoretic particles 34 may aggregate toward the first electrode layer 31 or the second electrode layer 33 according to an electric change on the first electrode layer 31 or the second electrode layer 33, and form the corresponding first reflective layer or second reflective layer.

The foregoing first electrode layer 31 and the foregoing second electrode layer 33 may both have a transparent conductive layered structure, so that light emitted by the light-emitting diode 20 may exit through the first electrode layer 31 or the second electrode layer 33.

In some implementations, the first electrode layer 31 and the second electrode layer 33 may be transparent conductive layered structures made of a material such as indium tin oxide.

The foregoing electrophoretic liquid 35 may be an electrophoretic liquid having a high transparency and refractive index, which can reduce energy loss of light emitted by the light-emitting diode 20 during transmission through the electrophoretic liquid 35.

The foregoing light-emitting diode 20 may have a cuboid structure, and the electrophoretic cavity 32 may include an upper cavity and a lower cavity that are disposed corresponding to the light-emitting diode 20. The electrophoretic cavity 32 further includes a connecting channel that communicates the upper cavity with the lower cavity, so that the upper cavity and the lower cavity are communicated into a whole.

In this implementation, one of the first electrode layer 31 and the second electrode layer 33 may be energized, so that the electrophoretic particles 34 aggregate on the energized electrode layer and form the corresponding reflective layer. In this way, light emitted by the light-emitting diode 20 is reflected by the reflective layer toward the side on which the non-energized electrode layer is located, and exits through the non-energized electrode layer, so that the first display surface 11 or the second display surface 12 of the display panel has a display function. Compared with the conventional technology in which two independent display panels need to be disposed to implement a double-sided display function of an electronic device, the solution of this application can effectively reduce the thickness of the display panel and reduce thickness costs of the display panel.

For example, during display on the first display surface 11, by energizing the second electrode layer 33, the electrophoretic particles 34 aggregate toward the second electrode layer 33 and form the first reflective layer, and light emitted by the light-emitting diode 20 is reflected by the first reflective layer and exits through the side on which the first electrode layer 31 is located, that is, a lighting-up display effect is formed on the first display surface 11. During display on the second display surface 12, by energizing the first electrode layer 31, the electrophoretic particles 34 aggregate toward the first electrode layer 31 and form the second reflective layer, and light emitted by the light-emitting diode 20 is reflected by the second reflective layer and exits through the side on which the second electrode layer 33 is located, that is, a lighting-up display effect is formed on the second display surface 12.

As shown in FIG. 5, the electrophoretic particle 34 includes a particle body 341 and a reflective layered structure 342 encapsulating the particle body 341. In this way, reflection efficiency of the electrophoretic particle 34 can be improved by disposing the reflective layered structure 342.

The reflective layered structure 342 may be an organic or inorganic coating having a high reflection property, for example, a metallic silver coating. The particle body 341 may be an organic or inorganic electrophoretic material, for example, titanium dioxide.

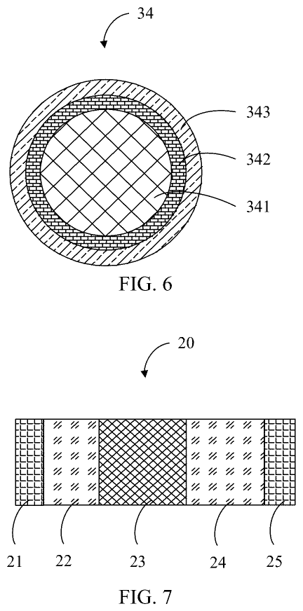

As shown in FIG. 6, the electrophoretic particle 34 further includes a protective layer 343, and the protective layer 343 encapsulates the reflective layered structure 342. In this way, by disposing the protective layer 343, collision deformation of the reflective layered structure 342 after the electrophoretic particle 34 is used for a long time can be reduced, and a reflection effect of the reflective layer formed by the electrophoretic particles 34 on light emitted by the light-emitting diode 20 can be reduced. The protective layer 343 may be an organic coating, for example, a resin layer.

As shown in FIG. 7, the light-emitting diode 20 includes a third electrode layer 21, a first semiconductor layer 22, a light-emitting layer 23, a second semiconductor layer 24, and a fourth electrode layer 25 that are arranged in a stacked manner, and the light-emitting diode 20 may have a vertical structure.

The first semiconductor layer 22 may be a P-type semiconductor, and the second semiconductor layer 244 may be an N-type semiconductor. The light-emitting layer 23 may have a single quantum well structure or a multi-quantum well structure. The P-type semiconductor may be connected to a positive terminal of a power supply, that is, the third electrode layer 21 may be connected to the positive terminal of the power supply. The N-type semiconductor may be connected to a negative terminal of the power supply, that is, the fourth electrode layer 25 may be connected to the negative terminal of the power supply.

In some implementations, the light-emitting diode 20 may alternatively have a face-up structure or a flip-chip structure.

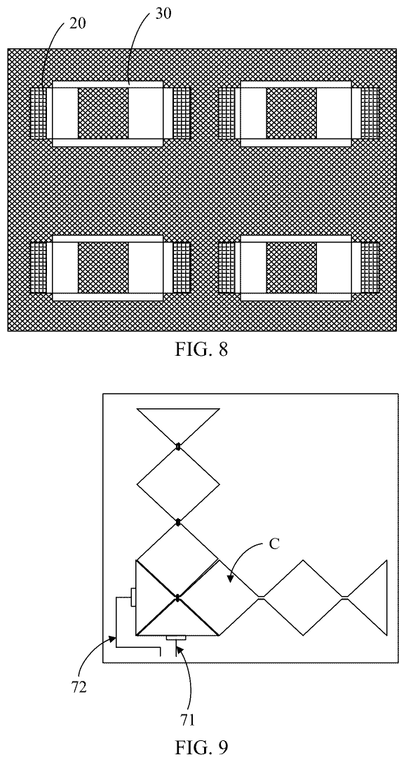

As shown in FIG. 8, the light-emitting diode 20 may be disposed in the electrophoretic structure 30 in a penetrating manner. For example, the light-emitting diode 20 may be disposed in the electrophoretic cavity 32 in a penetrating manner, and the light-emitting layer 23 is located inside the electrophoretic cavity 32. By means of such disposing, light emitted by the light-emitting diode 20 can exit through the first electrode layer 31 or the second electrode layer 33, so as to meet a double-sided display requirement of the display panel.

Optionally, the first electrode layer 31 and the second electrode layer 33 are both touch sensing layers. For example, the first electrode layer 31 and the second electrode layer 33 both have a touch sensing function. That is, the first electrode layer 31 and the second electrode layer 33 may be used as touch sensing layers of the display panel. By means of such disposing, an additional touch sensing layer is avoided, and a stack thickness of the display panel is reduced.

For example, during display on the first display surface 11, the electrophoretic particles 34 aggregate on the second electrode layer 33 and form the first reflective layer, so that the first electrode layer 31 serves as the touch sensing layer of the display panel. During display on the second display surface 12, the electrophoretic particles 34 aggregate on the first electrode layer 31 and form the second reflective layer, so that the second electrode layer 33 serves as the touch sensing layer of the display panel.

In some implementations, the first electrode layer 31 and the second electrode layer 33 may be designed as capacitive touch sensing layers. It may be understood that the first electrode layer 31 and the second electrode layer 33 may alternatively be designed as touch sensing layers of other forms, provided that a touch sensing function of the display panel can be implemented.

In addition, in this application, the first electrode layer 31 and the second electrode layer 33 are used as the touch sensing layers of the display panel, and the function can also be time-division multiplexed with an electrophoretic function. For example, when the first electrode layer 31 is energized and an aggregated layer of electrophoretic particles 34 is formed on a side on which the first electrode layer 31 is located, light emitted by the light-emitting diode 20 exits through the second electrode layer 33, so that the second electrode layer 33 is used as a touch function layer of the display panel, to meet a touch requirement of the display panel. Correspondingly, when the second electrode layer 33 is energized and an aggregated layer of the electrophoretic particles 34 is formed on a side on which the second electrode layer 33 is located, light emitted by the light-emitting diode 20 exits through the first electrode layer 31, so that the first electrode layer 31 is used as the touch function layer of the display panel, to meet a touch requirement of the display panel.

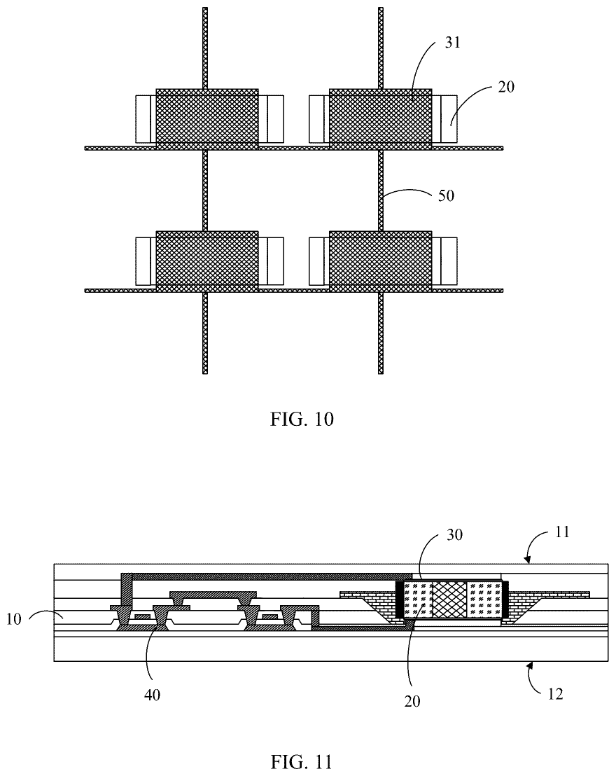

As shown in FIG. 9 and FIG. 10, a touch sensing channel in the first electrode layer 31 or the second electrode layer 33 includes a touch transverse sensing channel 71 and a touch longitudinal sensing channel 72. When a finger touches, a capacitive change occurs at a touch position, and coordinates of the touch position are positioned, so as to implement a touch function of the display panel.

As shown in FIG. 10, the first electrode layers 31 corresponding to the light-emitting diodes 20 may be connected by using a connecting channel 50, to form a touch sensing channel of the display panel. Correspondingly, the second electrode layers 33 corresponding to the light-emitting diodes 20 may further be connected by using a corresponding connecting channel, to form the touch sensing channel of the display panel.

In addition, the touch sensing channel may be electrically connected to a touch controller chip of the display panel. The touch controller chip may determine, based on a signal acquired by the touch sensing channel, which surface of the display panel is used, output a touch signal to an electrode layer on a side on which the used surface of the display panel is located, to endow the display panel with a touch sensing function, and output an electrophoretic control signal to another surface, to allow the electrophoretic particles 34 in the electrophoretic cavity 32 to aggregate toward the surface and form a corresponding reflective layer.

In some implementations, the touch controller chip may be a control chip on an electronic device including a display panel. The chip may be integrated and disposed in the display panel, or may be integrated and disposed on a mainboard of the electronic device, and the display panel may be electrically connected to the mainboard of the electronic device.

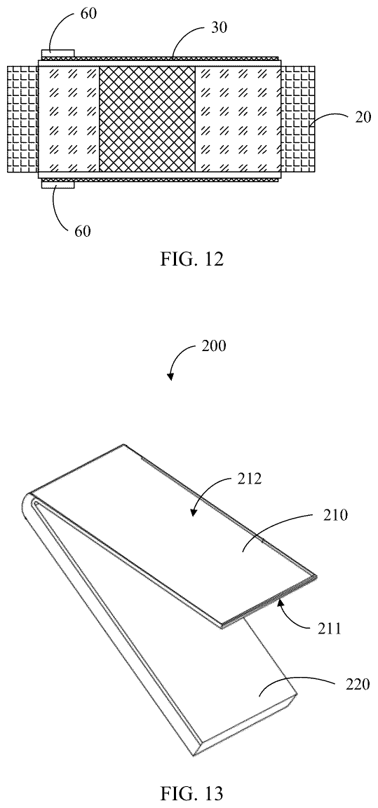

As shown in FIG. 11 and FIG. 12, the light-emitting diode 20 and the electrophoretic structure 30 are of an integral structure, and the light-emitting diode 20 and the electrophoretic structure 30 that are of the integral structure may be disposed on the display panel body 10 as a whole.

The foregoing light-emitting diode 20 and the foregoing electrophoretic structure 30 are of an integral structure, and may be directly disposed on the display panel body 10 in a manner of an independent device. Compared with a manner of first disposing the light-emitting diode 20 on the display panel body 10 and then disposing the electrophoretic structure 30 corresponding to the light-emitting diode 20, this manner can effective simplify an assembly process of the display panel.

For the light-emitting diode 20 and the electrophoretic structure 30 that are of an integrated structure, a corresponding contact layer 60 may be disposed on an electrode layer of the electrophoretic structure 30, so that the electrode layer is electrically connected to the driver circuit 40 of the display panel through the corresponding contact layer 60 and then the display function of the display panel is implemented.

It may be understood that the corresponding contact layer 60 is disposed on each of the first electrode layer 31 and the second electrode layer 33 of the electrophoretic structure 30, and the contact layer 60 may be disposed at an edge position of the first electrode layer 31 or the second electrode layer 33, to prevent the contact layer 60 from blocking light emitted by the light-emitting diode 20.

An embodiment of this application further provides an electronic device including the foregoing display panel.

It should be noted that the implementations of the foregoing display panel embodiments are also applicable to the embodiment of the electronic device, and can achieve a same technical effect. Details are not described herein again.

The foregoing electronic device may be a double-sided display mobile phone, a foldable mobile phone, or the like.

In some implementations, the electronic device may be a foldable mobile phone 200 shown in FIG. 13, including a first folding part 210 and a second folding part 220. The first folding part 210 includes the foregoing display panel, so that both a front surface and a back surface of the first folding part 210 can implement displaying.

For example, when the foldable mobile phone 200 is unfolded, an inner screen 211 of the first folding part 210 implements displaying, and when the foldable mobile phone 200 is folded, an outer screen 212 of the first folding part 210 implements displaying.

In the descriptions of this specification, descriptions using reference terms “an embodiment”, “some embodiments”, “an example embodiment”, “an example”, or “some examples” mean that features, structures, materials, or characteristics described with reference to the embodiment or example are included in at least one embodiment or example of this application. In this specification, example descriptions of the foregoing terms do not necessarily refer to a same embodiment or example. In addition, the described features, structures, materials, or characteristics may be combined in a proper manner in any one or more of the embodiments or examples.

Although the embodiments of this application have been illustrated and described, a person of ordinary skill in the art may understand that various changes, modifications, replacements, and variations may be made to the embodiments without departing from the principles and spirit of this application, and the scope of this application is as defined by the appended claims and their equivalents.

What is claimed is:

1. A display panel, comprising:
a display panel body, wherein the display panel body comprises a first display surface and a second display surface that are disposed in a back-to-back manner;
a light-emitting diode, wherein the light-emitting diode is disposed on the display panel body; and
an electrophoretic structure, wherein the electrophoretic structure is disposed on the display panel body, the electrophoretic structure is located between the first display surface and the second display surface, the electrophoretic structure comprises a first electrode layer, an electrophoretic cavity, and a second electrode layer that are sequentially disposed in a stacked manner, the electrophoretic cavity is disposed corresponding to the light-emitting diode, the first electrode layer is disposed on a side on which the first display surface is located, the second electrode layer is disposed on a side on which the second display surface is located, and the electrophoretic cavity is filled with an electrophoretic liquid and electrophoretic particles, wherein
during display on the first display surface, the electrophoretic particles aggregate on the second electrode layer and form a first reflective layer; and
during display on the second display surface, the electrophoretic particles aggregate on the first electrode layer and form a second reflective layer.

2. The display panel according to claim 1, wherein during display on the first display surface, the electrophoretic particles aggregate on the second electrode layer and form the first reflective layer, and the first electrode layer serves as a touch sensing layer of the display panel.

3. The display panel according to claim 1, wherein during display on the second display surface, the electrophoretic particles aggregate on the first electrode layer and form the second reflective layer, and the second electrode layer serves as a touch sensing layer of the display panel.

4. The display panel according to claim 1, wherein the electrophoretic particle comprises a particle body and a reflective layered structure encapsulating the particle body.

5. The display panel according to claim 4, wherein the electrophoretic particle further comprises a protective layer, and the protective layer encapsulates the reflective layered structure.

6. The display panel according to claim 4, wherein the reflective layered structure is a metallic silver coating disposed for encapsulating the particle body.

7. The display panel according to claim 1, wherein the display panel further comprises a driver circuit, and the driver circuit is electrically connected to the first electrode layer and the second electrode layer respectively.

8. The display panel according to claim 1, wherein the light-emitting diode has a vertical structure, and comprises a third electrode layer, a first semiconductor layer, a light-emitting layer, a second semiconductor layer, and a fourth electrode layer that are disposed in a stacked manner.

9. The display panel according to claim 8, wherein the light-emitting diode is disposed in the electrophoretic cavity in a penetrating manner, and the light-emitting layer is located inside the electrophoretic cavity.

10. An electronic device, comprising a display panel, wherein the display panel comprises:
a display panel body, wherein the display panel body comprises a first display surface and a second display surface that are disposed in a back-to-back manner;
a light-emitting diode, wherein the light-emitting diode is disposed on the display panel body; and
an electrophoretic structure, wherein the electrophoretic structure is disposed on the display panel body, the electrophoretic structure is located between the first display surface and the second display surface, the electrophoretic structure comprises a first electrode layer, an electrophoretic cavity, and a second electrode layer that are sequentially disposed in a stacked manner, the electrophoretic cavity is disposed corresponding to the light-emitting diode, the first electrode layer is disposed on a side on which the first display surface is located, the second electrode layer is disposed on a side on which the second display surface is located, and the electrophoretic cavity is filled with an electrophoretic liquid and electrophoretic particles, wherein
during display on the first display surface, the electrophoretic particles aggregate on the second electrode layer and form a first reflective layer; and
during display on the second display surface, the electrophoretic particles aggregate on the first electrode layer and form a second reflective layer.

11. The electronic device according to claim 10, wherein during display on the first display surface, the electrophoretic particles aggregate on the second electrode layer and form the first reflective layer, and the first electrode layer serves as a touch sensing layer of the display panel.

12. The electronic device according to claim 10, wherein during display on the second display surface, the electrophoretic particles aggregate on the first electrode layer and form the second reflective layer, and the second electrode layer serves as a touch sensing layer of the display panel.

13. The electronic device according to claim 10, wherein the electrophoretic particle comprises a particle body and a reflective layered structure encapsulating the particle body.

14. The electronic device according to claim 13, wherein the electrophoretic particle further comprises a protective layer, and the protective layer encapsulates the reflective layered structure.

15. The electronic device according to claim 13, wherein the reflective layered structure is a metallic silver coating disposed for encapsulating the particle body.

16. The electronic device according to claim 10, wherein the display panel further comprises a driver circuit, and the driver circuit is electrically connected to the first electrode layer and the second electrode layer respectively.

17. The electronic device according to claim 10, wherein the light-emitting diode has a vertical structure, and comprises a third electrode layer, a first semiconductor layer, a light-emitting layer, a second semiconductor layer, and a fourth electrode layer that are disposed in a stacked manner.

18. The electronic device according to claim 17, wherein the light-emitting diode is disposed in the electrophoretic cavity in a penetrating manner, and the light-emitting layer is located inside the electrophoretic cavity.
